(19) United States
(12) Patent Application Publication
(10) Pub. No.: US 2006/0106741 A1
(43) Pub. Date: May 18, 2006

(54) Utility monitoring system and method for relaying personalized real-time utility consumption information to a consumer

(75) Inventor: Rajalingam Janarthanan, Brooklyn, NY (US)

Correspondence Address: WOLF BLOCK SCHORR AND SOLIS-COHEN LLP, 205 PARK AVENUE, NEW YORK, NY, 10177, US

(73) Assignee: San Vision Energy Technology Inc.

(21) Appl. No.: 11/184,140

(22) Filed: Jul. 19, 2005

Related U.S. Application Data
(60) Provisional application No. 60/628,904, filed on Nov. 17, 2004.

(51) Int. Cl. G01R 21/133; G01R 11/56

(52) U.S. Cl. 705/412

(57) ABSTRACT

A utility monitoring system and method for relaying to a consumer personalized utility consumption information in order to induce the consumer to conserve the utility. The system includes a data source, a processor coupled to the data source, and a display unit coupled to the processor. The processor receives utility consumption information from the data source. The processor then generates enhanced utility consumption information, as well as a display of the data. The processor may also provide Demand-Side Management for utility conservation based on the utility consumption information and the consumer's settings. The display is then transmitted to the display unit to be displayed. The display unit resides in the consumer's home or business. A broadband server may also be used to provide customized broadband information.

This patent application claims the benefit of U.S. provisional patent application 60/628,904, filed Nov. 17, 2004.

### FIELD OF THE INVENTION

The present invention generally relates to electronic devices, and in particular, to utility (i.e. electricity, gas and water) monitoring systems and methods for relaying personalized utility consumption information to a consumer.

### BACKGROUND OF THE INVENTION

Presently, we live in an era of electricity blackouts and escalating utility costs due to the growing divergence between the increasing power demand and the decreasing generation capabilities. A number of initiatives have surfaced to counter this dilemma. The proposed solutions include searching for alternative energy sources, higher efficiency energy devices, and energy conservation methods.

An effective method of utility conservation is reducing consumer consumption by changing a consumer's utility consumption practices. For example, a consumer may turn off lights not being used or use the dishwasher during off-peak hours. Encouraging awareness of consumption patterns not only reduces the overall energy demand, but also results in consumers saving significant money on their monthly energy bill. Studies have shown that consumers adjust their utility consumption when informed of their current consumption and related costs.

However, most consumers are unaware of the rate and cost of their utility consumption. The problem for most consumers is that their home utility meter, which measures their utility consumption, is in an obscure place, such as in their basement or outside their home. Furthermore, the utility meters only provide the quantity of the utility being consumed. No cost data is displayed. Most consumers only become aware of the rate and cost of their utility consumption when they receive a monthly or quarterly statement from a utility company. By that time it is too late for the consumers to take any actions that would curb their utility consumption.

Consumers that are aware of their utility consumption may still find it difficult to gauge whether their utility consumption should be reduced because they have no point of reference as to what would constitute an appropriate level of consumption. The only reference currently available to a consumer is the consumer's previous utility bills. Calculating whether the current utility consumption will exceed that of a previous month can be quite difficult and tedious. Most consumers would undoubtedly not examine their previous bills to determine appropriate utility consumption levels.

Consumers can also be encouraged to conserve through the use of conservation tips. Many environmental groups, as well as utility companies, provide suggestions to consumers on methods of conserving utilities. For example, information about utility conservation is available on the internet and in various publications. Most consumers, however, do not have the time or the desire to research the conservation information. A system is required that would make conservation information, along with other important utility information, readily available to the consumer.

Another method of reducing consumer energy consumption is to implement Demand-Side Management (DSM) support. This technology allows a service to help a consumer conserve a utility by decreasing the utility consumption of the consumer from a remote location. Generally, DSM support operates by allowing a server to reduce the utility consumption of appliances within the consumer's home via an internet connection. Examples could be reducing a thermostat or shutting down a boiler during peak hours. However, until now, DSM has not used peak cost, aggregate consumption, or forecasted consumption and cost of consumption values as the factors for determining when to reduce the utility consumption. Furthermore, DSM has not been able to make customized adjustments to individual locations based on data taken from those locations.

Therefore, for the reasons stated above, there is currently a need for a utility monitoring system and method for relaying to a consumer personalized real-time utility consumption information, as well as utility conservation information, and providing improved Demand-Side Management support.

### OBJECTS AND SUMMARY OF THE INVENTION

Accordingly, it is a primary object of the present invention to provide a new and improved utility monitoring system and method for relaying personalized utility consumption information to a consumer that overcomes the shortcomings of prior art systems.

Another object of the present invention is to provide a new and improved utility monitoring system and method for relaying to a consumer the consumer's utility consumption information.

Still another object of the present invention is to provide a new and improved utility monitoring system and method for relaying to a consumer the cost of the consumer's utility consumption.

Yet another object of the present invention is to provide a new and improved utility monitoring system and method for relaying to a consumer utility pricing information.

A further object of the present invention is to provide a new and improved utility monitoring system and method for relaying to a consumer a comparison of utility consumption information of a first period with the consumer's utility consumption information from a prior period.

Still a further object of the present invention is to provide a new and improved utility monitoring system and method for relaying to a consumer a forecast of the cost of future utility consumption.

Yet a further object of the present invention is to provide a new and improved utility monitoring system and method that facilitates Demand-Side Management support based on real-time utility consumption and cost information, as well as peak cost and aggregate consumption data.

Another object of the present invention is to provide a new and improved utility monitoring system and method for relaying broadband content to a consumer.

Yet another object of the present invention is to provide a new and improved utility monitoring system and method for relaying utility messages, as well as targeted advertisements, to a consumer.

Briefly, these and other objects are attained by providing a new and improved utility monitoring system and method for relaying personalized utility consumption information to a consumer including a data source, a processor, and a display unit. Utility consumption information includes consumption of a utility, price of a utility, and cost of a utility.

The data source sends utility consumption information to the processor via a communication medium. Embodiments of the data source include a conventional utility meter customized to transmit the utility consumption information to the processor, a remote server that transmits the utility consumption information to the processor, a base meter mounted to a conventional utility meter to capture the utility consumption information and transmit it to the processor, or a base meter that is directly connected to a utility source, such as the electrical power line, to obtain its own measurements of the utility consumption information and transmit that information to the processor.

The processor receives the utility consumption information and executes software that carries out a method of generating a display of the utility consumption information. The processor also executes software that generates enhanced utility consumption information utilizing the utility consumption information received from the data source. The enhanced utility consumption information includes a comparison of utility consumption of a first and second time period, cost of utility consumption over a period, a comparison of cost of utility consumption of a first and second time period, a forecast of the future value of the utility consumption information, and a comparison of a forecast of utility consumption information of a current time period with that of a previous time period. The processor can also generate a display of the enhanced utility consumption information. The generated displays are transmitted to the display unit via the communication medium.

The processor can also execute software that provides Demand-Side Management support utilizing the utility consumption data or the enhanced utility consumption data.

The display unit includes a screen upon which the displays, generated by the processor, are displayed. The display unit can also display broadband content received from a Broadband server via a network connection, such as ethernet. The utility company may send messages regarding the utility for display on the display unit. Targeted advertisements may also be displayed to the consumer on the display unit.

### BRIEF DESCRIPTION OF THE DRAWINGS

A more complete appreciation of the present invention and many of the attendant advantages thereof will be readily understood by reference to the following detailed description when considered in connection with the accompanying drawings, in which:

FIG. 1 is a schematic illustration of a utility monitoring system for relaying personalized real-time utility consumption information to a consumer according to the present invention;

FIG. 2 is a schematic illustration of a base meter, used in the utility monitoring system, mounted on a conventional utility meter according to the present invention;

FIG. 3 is a schematic illustration of the base meter shown in FIG. 2, used in the utility monitoring system of FIG. 1, illustrating the components of the base meter according to the present invention;

FIG. 4 is a schematic illustration of a display unit of the utility monitoring system, illustrating the components of the display unit according to the present invention;

FIG. 5 is a front view of the display unit of the utility monitoring system shown in FIG. 4 according to the present invention;

FIG. 6 is a flow chart of a method of displaying a comparison of the consumption of a utility for a first and second time period according to the present invention;

FIG. 7 is a flow chart of a method of displaying a value related to the price of a utility for a time period;

FIG. 8 is a flow chart of a method of displaying a comparison of the price of a utility for a first and second time period;

FIG. 9 is a flow chart of a method of displaying the cost of the consumption of a utility for a time period according to the present invention;

FIG. 10 is a flow chart of a method of displaying a comparison of the cost of the consumption of a utility for a first and second time period according to the present invention;

FIG. 11 is a flow chart of a method of displaying a forecast of the value of utility consumption information for a time period according to the present invention; and

FIG. 12 is a flow chart of a method for providing Demand-Side Management to a location according to the present invention.

### DETAILED DESCRIPTION OF THE INVENTION

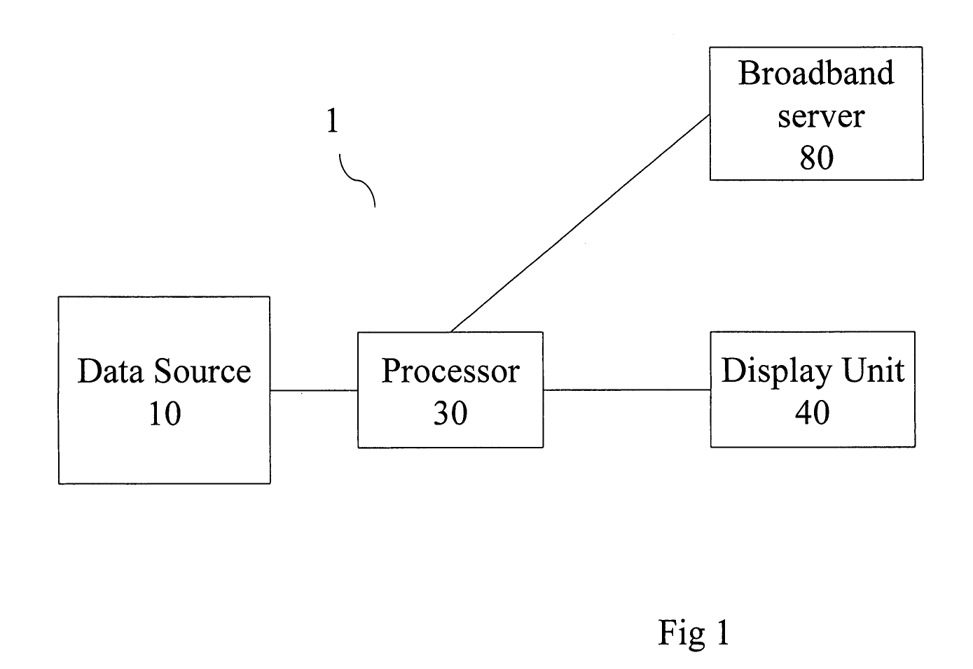

The invention will now be described with reference to FIGS. 1 to 5, which in general disclose a preferred embodiment of a new and improved utility monitoring system and method for relaying to a consumer personalized utility consumption information. In the figures, like reference characters designate identical or corresponding parts or steps throughout the several views. It is understood that the figures represent only a preferred embodiment of the invention.

Referring now to FIG. 1, a utility monitoring system for relaying to a consumer personalized real-time utility consumption information in accordance with the present invention is identified generally by reference numeral 1. The utility monitoring system 1 includes a data source 10, a processor 30 coupled to the data source 10, and a display unit 40 coupled to the processor 30. The utility monitoring system 1 may also include a broadband server 80 coupled to either the processor 30 or the display unit 40. It is understood that the components of the utility monitoring system 1 may be part of the same device or may be remotely coupled to each other. It is also understood that the utility monitoring system 1 may be used at locations other than a home including commercial, industrial and institutional facilities.

The components are coupled through a communication medium. The communication medium may be power line communication, radio frequency communication, ethernet communication, coaxial communication, phone cables, or any other form of communication known in the art. It is understood that each component is equipped with an appropriate interface for communicating via the particular communication medium employed. It is also understood that a plurality of different communication media may be used, which would require each component of the utility monitoring system 1 to have several communication interfaces.

The data source 10 relays utility consumption information at predetermined time intervals to the processor 30. The utility consumption information can be the consumption of a utility, the price of a utility, the cost of consumption of a utility, or any other information relating to the consumption of a utility. The utility consumption information is transmitted from the data source 10 to the processor 30 via a communication medium. It is understood that the processor 30 may be coupled to the data source 10 remotely or as components of the same device. It is also understood that there may be more than one data source. For example, there may be one data source for price of a utility, and a second data source for the consumption of a utility.

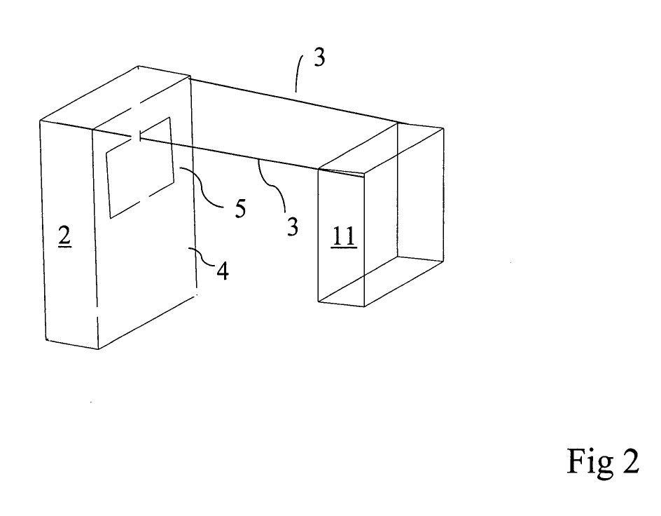

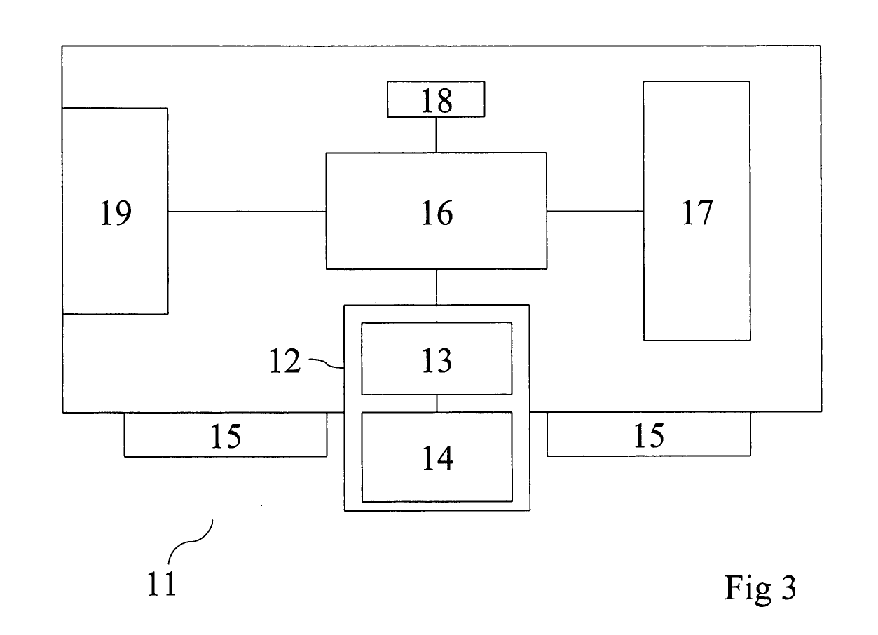

The data source 10 may be a utility meter, a remote server, or a base meter 11 (FIGS. 2 and 3). A utility meter used as the data source 10 must be capable of transmitting utility consumption information to the processor 30. A conventional utility meter may be specially customized to transmit utility consumption information, such as consumption of a utility, to the processor 30 via a communication medium.

The remote server may be operated by a utility company. The utility consumption information is obtained and time stamped by the remote server by any means well known in the art. For example, a home utility meter may send utility consumption information to a utility company's remote server. The remote server time stamps and sends the utility consumption information to the processor 30 via a communication medium. In the preferred embodiment, a remote server is used as the data source for relaying the price of a utility.

FIGS. 2 and 3 show the data source 10 in the form of a base meter 11. The base meter 111 may be used when there is no remote server to supply the utility consumption information or when the utility meter cannot easily be adapted to provide the consumption information to the processor 30. As shown in FIG. 2, the base meter 11 may be mounted to a conventional utility meter 2 using a plurality of brackets 3. The utility meter 2 includes a meter face 4 and a plurality of meter dials 5 for indicating the consumer's utility consumption. Referring to FIG. 3, the base meter 11 includes an image reader 12, a plurality of lighting arrays 15, a digital signal processor 16, memory storage 17, a real-time clock 18, and a base meter communication module 19. It is understood that the base meter 11 must be mounted to the utility meter 2 in order that the image reader 12 completely covers the plurality of meter dials 5. The base meter 111 is easily detachable and portable, and may be installed without the assistance of a certified professional, such as an electrician.

The image reader 12 includes an image capture device 13 and a lens 14. The image capture device 13 captures utility readings displayed on the plurality of meter dials 5 at periodic time intervals, for example, intervals of every 15 minutes. The lens 14 of the image reader 12 must be aligned with the plurality of meter dials 5 so that the image capture device 13 can capture the entire utility reading. The plurality of lighting arrays 15 are used to illuminate the utility reading when the quality and quantity of light is insufficient, for example during the night. It is understood that the image reader 12 used in the present invention may be any conventional still camera or video technology, such as a charge coupled device (CCD) array or other known technologies and/or devices having the ability to capture an image. The image captured by the image capture device 13 is stored in the memory storage 17. It is understood that the image may also be stored in static memory within the image reader 12.

The Digital Signal Processor 16 executes code that contains an Optical Character Recognition (OCR) algorithm. The Digital Signal Processor 16 accesses the captured image from the memory storage 17, and extracts the utility reading contained within the image using the OCR algorithm. If the Digital Signal Processor 16 is unable to extract the utility reading from the captured image, the image capture device 13 will continue to capture new images until a utility reading is successfully obtained.

Once the utility reading is extracted by the Digital Signal Processor 16, the utility reading is time-stamped by the real-time clock 18 and sent to the base meter communication module 19. The base meter communication module 19 is an interface that converts data received from the Digital Signal Processor 16 and translates it into a form that can be transmitted over a communication medium to the processor 30.

Referring back to FIG. 1, the data source 10 sends the utility consumption information to the processor 30 via a communication medium. The utility consumption information is transmitted by the data source 10 at predetermined time intervals. In the preferred embodiment, the time intervals are of equal duration. Often, the consumer is not interested in the utility consumption data for a given time interval, but is more interested in the aggregate utility consumption data over a time period. The time period is made up of at least one time interval, but preferably a plurality of equal time intervals. The time periods are generally for longer durations of time such as a week, a month, or a year. However, the time periods may be any duration of time. The time intervals which make up the time periods are generally short such as a day, an hour, a minute, or even as short as a fraction of a second. It is understood that the shorter the time intervals, the closer the utility consumption information obtained from the data source is to being a real-time value. Real-time value is the current or actual value of the consumption information being measured or a value that is close enough to the current value to provide a consumer with the sense of the current value. An advantage of having real-time utility consumption information is that it allows the consumer to employ appropriate utility conservation measures based on the current value of the utility consumption information rather than on old data in which case (where) it may be too late to take appropriate action.

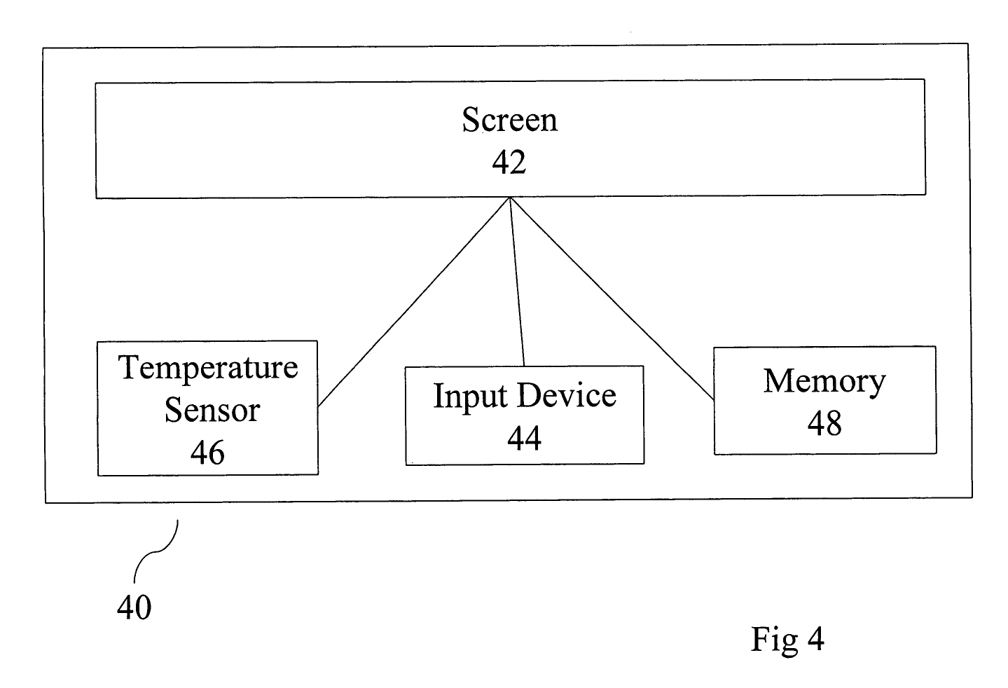

The processor 30 receives the utility consumption information for each time interval from the data source 10. The processor 30 stores the utility consumption information into either its own memory or the memory 48 of the display unit 40 (FIG. 4) such that the utility consumption information can be referenced by time period and by time interval. Storing the utility consumption information into memory creates historical records of the data for use in data comparisons and forecasts.

The processor 30 executes software that generates a display of the utility consumption information. The display is then transmitted to the display unit 40 to be displayed. The processor 30 may also execute software that generates enhanced utility consumption information utilizing the utility consumption information received from the data source 10. A display of the enhanced utility consumption information may also be generated and transmitted to the display unit 40 for display.

Referring to FIG. 4, the display unit 40 includes a screen 42 which displays the displays. The display unit 40 may be remotely coupled to the processor 30, or it may be coupled to the processor as components of the same device. In the preferred embodiment, the processor 30 and the display unit 40 are components of the same device, and are remotely coupled to at least one data source 10. The display unit may also display broadband content received from the broadband server or messages received from a remote server administered by the utility company. Targeted advertisements may also be displayed on the display unit 40.

The screen 42 may be an LED or LCD screen or any other type of display unit well known in the art. It is also understood that the display unit 40 may include multiple screens in order to separately display numerically displayed data from graphically displayed data.

In the preferred embodiment, the display unit 40 is located in an area where it can be seen by the consumer on a regular basis. It is also preferable for the display unit 40 to be battery operated and portable so that the consumer can move it to more accessible areas of the location. The more visible the display unit 40 is to the consumer, the more encouragement it provides to conserve the monitored utility.

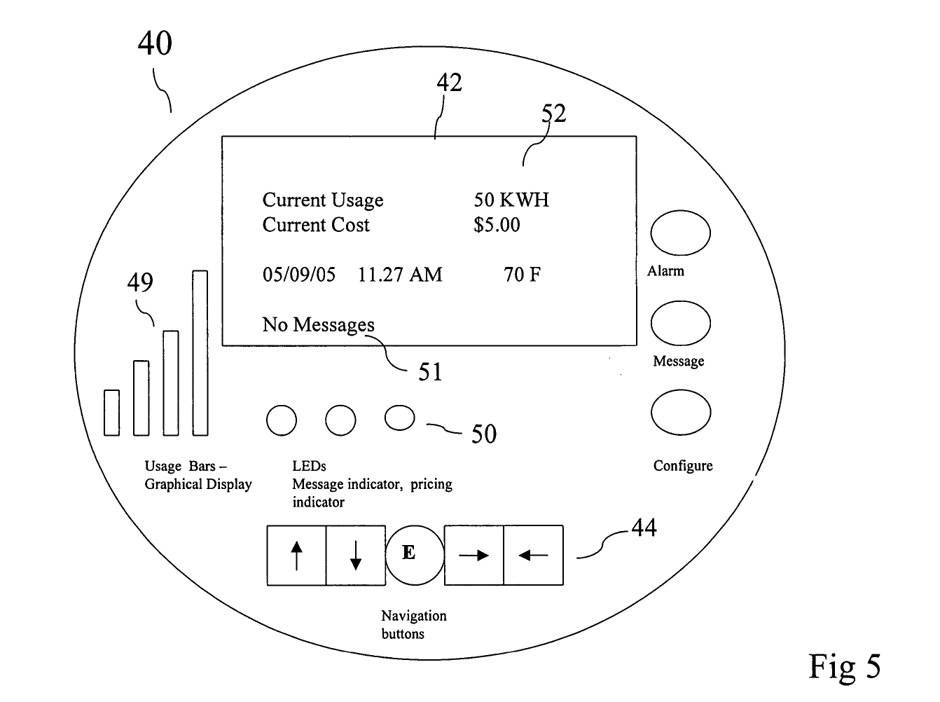

In the preferred embodiment the display unit 40 also includes an input device 44 having a plurality of membrane keys, as shown in FIG. 5, or any other means of inputting or selecting data known in the art. The input device 44 allows the consumer to select the type of data to be displayed on the screen 42 and to scroll through the displayed data. For example, the consumer may use the input device 44 to select the utility consumption information which will be displayed, as well as the types of broadband content the display unit 40 receives. The input device may also be used to configure the Demand-Side Management service provided by the processor 30, as detailed below.

The display unit 40 may also include a temperature sensor 46 for displaying the temperature on the screen 42 and for transmitting the temperature at the location to the processor 30 for use in Demand-Side Management.

Referring to FIG. 5, the displays may be graphical 49 or color coded or both. Color coded means that the color of the display has some significance. For example, a green bar may indicate that this month's consumption is less than 50% of the previous month's consumption; an orange bar may indicate that this month's consumption is between 51% and 75% of last month's consumption; a red bar may indicate that this month's consumption is between 76% to 100% of last month's consumption; and a flashing red bar could indicate that this month's consumption is greater than last month's consumption. It is understood that some of the information may be displayed graphically 49, while the rest is displayed alpha-numerically 52. Furthermore, colored LED lights 50 and/or a scrolling text message 51 displayed on the screen 42 may be used to indicate to the consumer that the current price of the utility is high or low. For example, if after processing the utility pricing data the display unit 40 determines that the current price of the utility is high, a red LED light is illuminated. Conversely, if the utility pricing is relatively low a green LED is illuminated. The displayed utility price allows consumers to easily determine the price of a utility in order to implement appropriate conservation measures. Graphical and color coded displays present the data in a manner that is easily readable by the consumer, even from a distance. The displays encourage the consumer to take action to conserve the utility by reducing their consumption.

The display unit 40 receives broadband content from the broadband server 80 (FIG. 1) via a communications medium. The role of the broadband server 80 is to provide user-selected broadband content (news, weather, sports etc.) to the display unit 40. The broadband server 80 may be a remote server that provides broadband content from the internet or a database. The broadband content may be selected using the input device 44. The selected broadband content is received by the display unit 40 and displayed on the screen 42. The broadband content may include utility conservation tips, news, weather, sports, targeted advertisements, etc. as well as other types of content. It is understood that the broadband server may be coupled to the display unit 40 via the processor 30.

The processor 30 may execute software that generates a display of the consumption of a utility for at least a portion of a time period. For each time interval of the time period, a consumption value, indicative of the consumption of a utility at that time interval, is obtained. If the consumption of a utility for only a portion of the time period is desired, a consumption value should be obtained for only those time intervals that constitute the desired portion of the time period. The consumption values are obtained from the data source 10 for each time interval of the desired portion of the time period. The processor 30 then generates a display of the obtained consumption values or a display of only the consumption values corresponding to the most recent time interval. The display is then transmitted to the display unit 40 to be displayed. It is understood that if the values received from the data source 10 are aggregate consumption values it may be desirable to subtract the value of the utility consumed prior to the time period from the consumption value at the end of the time period so that the utility consumption for only the desired time period is displayed.

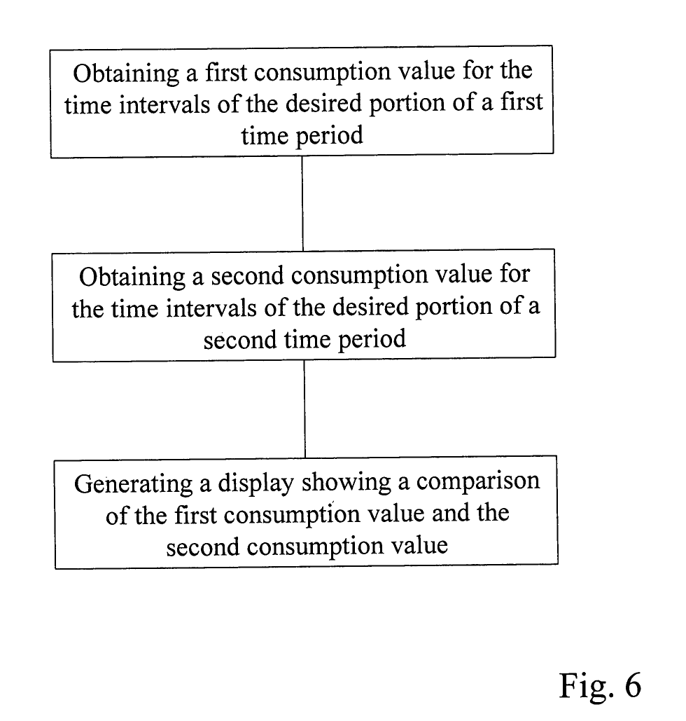

Referring to FIG. 6, the processor 30 may generate a display of a comparison of the consumption of a utility of at least a portion of a first time period with that of at least a portion of a second time period. In the preferred embodiment, the first and second time periods are of equal duration and are composed of time intervals of equal duration. However, it is understood that the first and second time periods, as well as their respective time intervals, may be of different durations. It is also understood that the first and second time periods may be separate and distinct time periods or may overlap. A first consumption value is obtained from the data source 10 for each time interval of the portion of the first time period to be compared. If the entire first time period is to be used in the comparison then a first consumption value for each of the time intervals must be obtained. A second consumption value is obtained for each of the time intervals of the portion of the second time period to be used in the comparison. The processor 30 then generates a display of a comparison of the first and second consumption values. The processor 30 then transmits the display to the display unit 40 to be displayed.

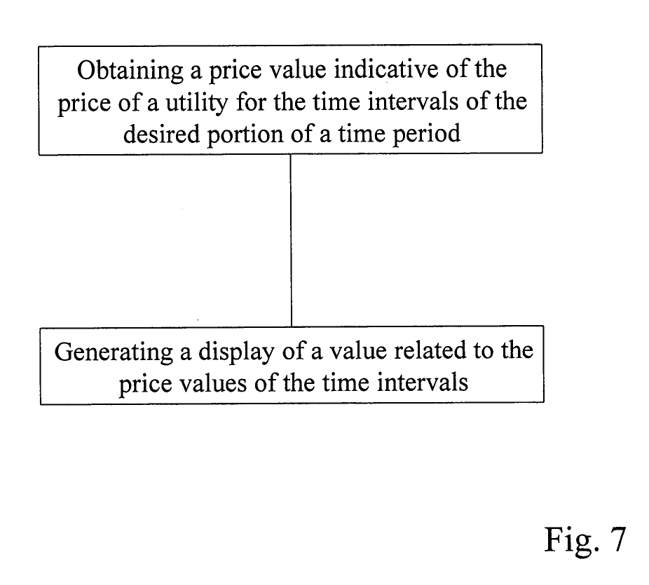

Referring to FIG. 7, the processor 30 generates a display of the price of a utility for at least a portion of a time period. Price values, indicative of the price of the utility for each time interval of the portion of the time period, are obtained from the data source 10 or may be manually set. The processor 30 then generates a display using the price values. This may be done by generating a display of the average price value. The processor 30 then transmits the display to the display unit 40 to be displayed.

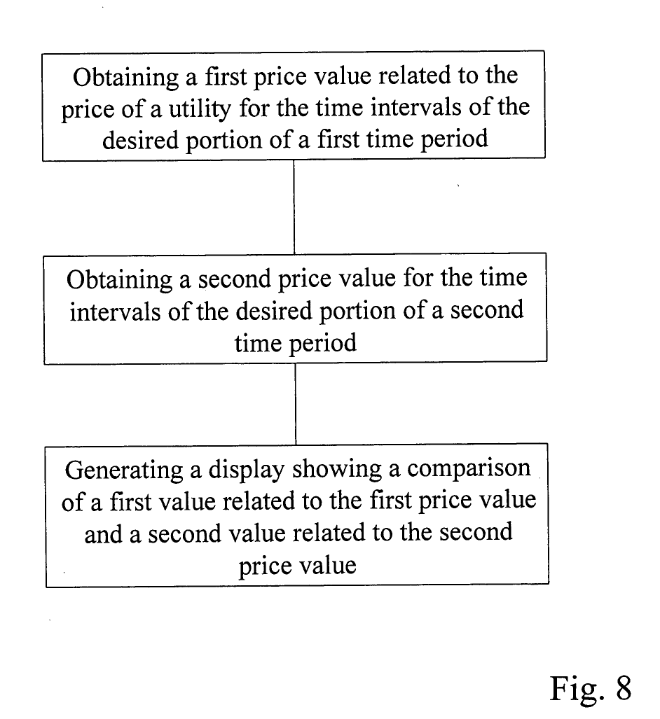

Referring to FIG. 8, the processor 30 may also execute a software program that generates a display of a comparison of the price of a utility of at least a portion of a first time period with the price of at least a portion of a second time period. In the preferred embodiment, the first and second time periods are of equal duration and are composed of time intervals of equal duration. However, it is understood that the first and second time periods, as well as their respective time intervals, may be of different durations. It is also understood that the first and second time periods may be separate and distinct time periods or may overlap. A first price value is obtained from the data source 10 for each time interval of the portion of the first time period to be compared. If the entire first time period is to be used in the comparison then a first price value for each of the time intervals must be obtained. A second price value is obtained for each time interval of the portion of the second time period to be used in the comparison. The processor 30 then generates a display of a comparison of the first and second price values. This may be done by comparing the average first price value with the average second price value. The processor 30 then transmits the display to the display unit to be displayed.

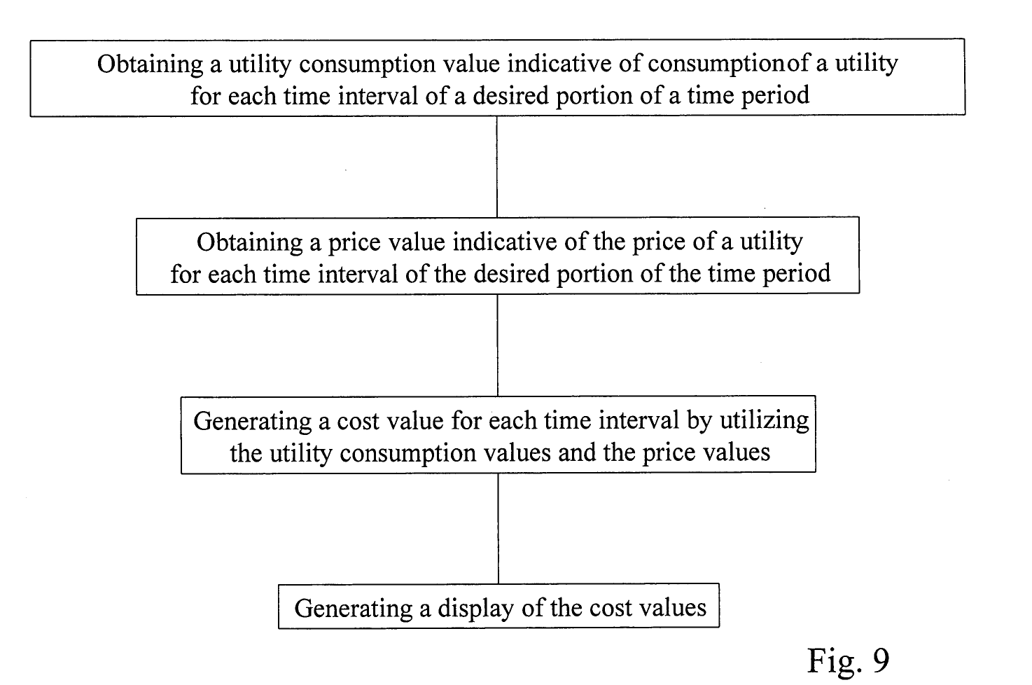

Referring to FIG. 9, the processor 30 may generate a display of the cost of consumption of a utility for at least a portion of a time period. For each time interval of the portion of the period, a consumption value, indicative of the consumption of a utility at the end of that time interval, is obtained from the data source 10. Price values, indicative of the price of the utility for each time interval of the portion of the time period, are obtained from a remote server or may be manually set. A cost value, indicative of the cost of consumption of the utility for the portion of said time period, is generated utilizing the consumption values and the price values. The cost value may be generated by multiplying the consumption values with the price values that correspond to the same time interval. Alternatively, only the consumption value that corresponds to the most recent time interval is multiplied by the price value that corresponds to the same time interval. The cost value may also be obtained using the consumption values and the average of the price values. It is understood that the processor 30 may generate a cost value for each time interval. The cost value or values may also be stored, for later use, in a memory storage such that they can be referenced and retrieved by time period and/or time interval. The processor 30 then generates a display of the cost value or values. The processor 30 transmits the display to the display unit 40 to be displayed.

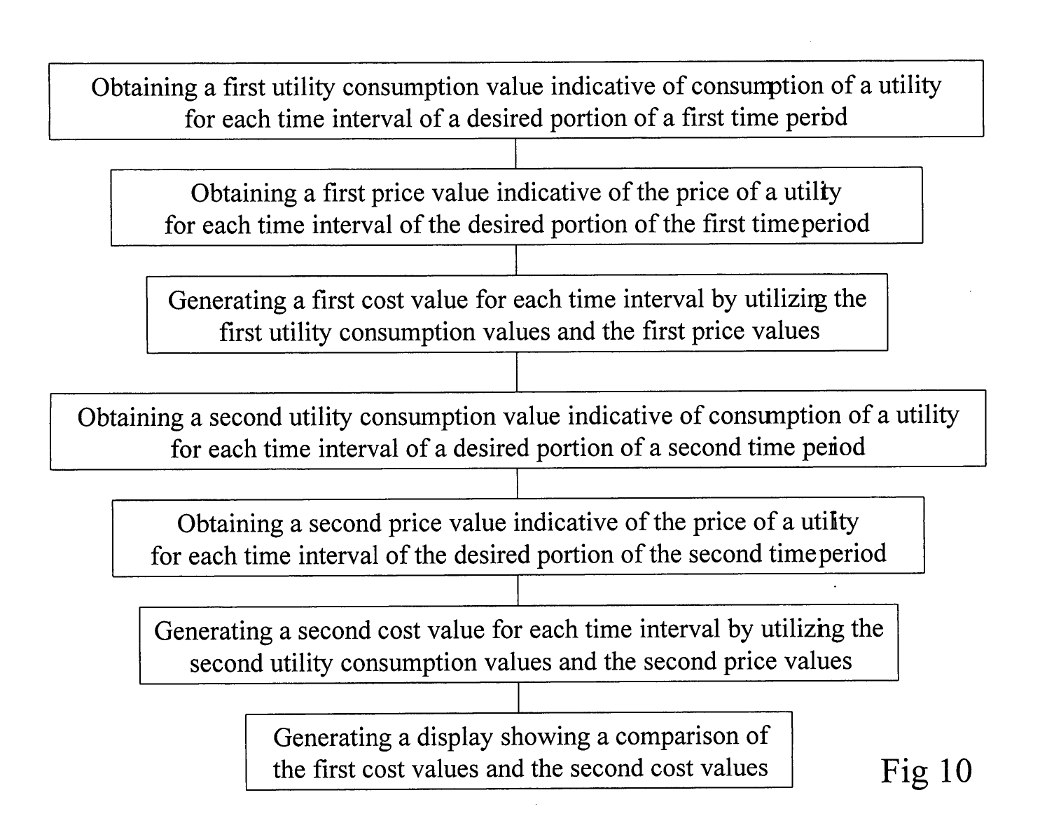

Referring to FIG. 10, the processor 30 may generate a display of a comparison of the cost of consumption a utility of at least a portion of a first time period with the cost of a utility of at least a portion of a second time period. In the preferred embodiment, the first and second time periods are of equal duration and are composed of time intervals of equal duration. However, it is understood that the first and second time periods, as well as their respective time intervals, may be of different durations. It is also understood that the first and second time periods may be separate and distinct time periods or may overlap. A first price value is obtained from the data source 10 for each time interval of the portion of the first time period to be compared. A first consumption value is obtained from the data source 10 for each time interval of the portion of the first time period to be compared. First cost values are generated by multiplying the first price values by the first consumption values of corresponding time intervals. Alternatively, the first cost values may be generated by multiplying the first consumption values by the average first price values obtained by taking the average of the first price values or by manually entering an average price. A second price value is obtained for each time interval of the portion of the second time period to be used in the comparison. A second consumption value is obtained from the data source 10 for each time interval of the portion of the second time period to be used in the comparison. Second cost values are then generated by multiplying the second consumption values by the second price values of the corresponding time intervals. Alternatively, the second cost values may be generated by multiplying the second consumption values by the average of the second consumption values or by a manually set average value. The processor 30 then generates a display of a comparison of the first and second cost values. The processor 30 transmits the display to the display unit 40 to be displayed.

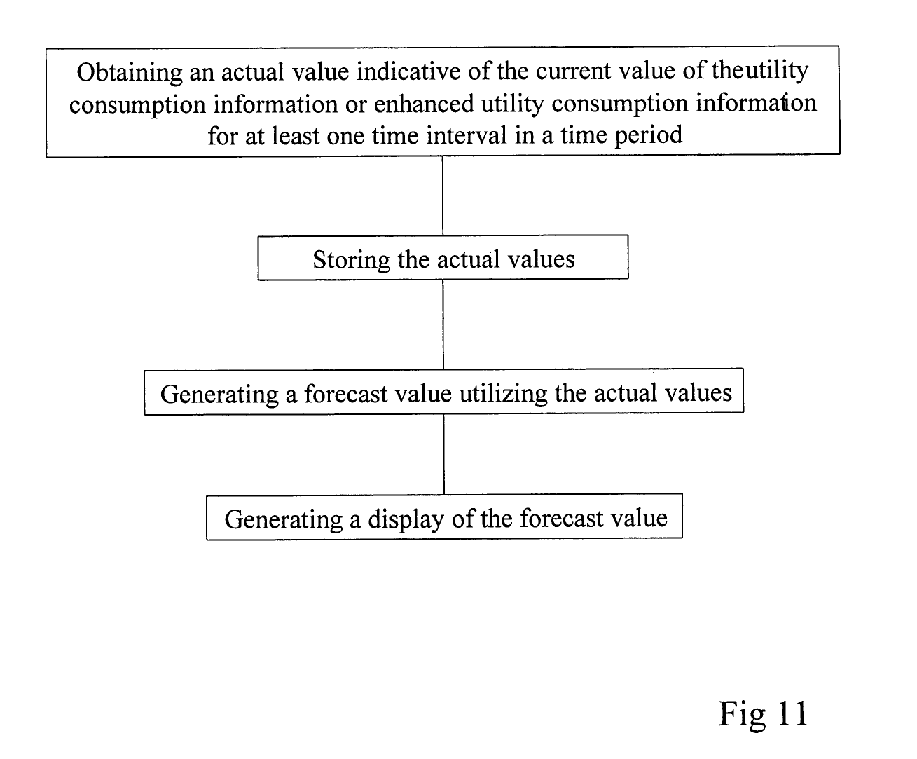

Referring to FIG. 11, the processor 30 may generate a forecast value, which is the future value of the utility consumption information or the enhanced utility consumption information, for at least one time interval. The forecast value may be the estimated value, at the end of a current time period or future time period, of consumption of a utility, price of a utility, or cost of consumption of a utility. The processor 30 obtains an actual value indicative of the current value of at least one type of utility consumption information or enhanced utility consumption information for the time intervals to be used in the forecast. The processor 30 then stores those values into memory. Using the actual values stored in the memory, the processor 30 generates a forecast value. Any algorithm for forecasting data known in the art may be used. An example of an algorithm that can be used to forecast the future value of the data is identifying a pattern in the data over a plurality of time intervals and calculating the future value based on the pattern. A second example of an algorithm for forecasting the future value of the data is determining a rate of consumption using consumption data obtained from the data source for a plurality of intervals and calculating the future value of the data based on the rate. A third forecasting algorithm forecasts the future value of the data to be equivalent to the value of the data at a past similar period. It is understood that these are only examples of algorithms that can be used by the processor 30 to forecast the future value of data related to the consumption of a utility. Any algorithm known in the art may be used.

Once the forecast value has been generated by the processor 30, a display of the forecast value may be generated and transmitted to the display unit 40 to be displayed. A display of a comparison of the forecast value for the end of a time period and utility consumption information or enhanced utility consumption information for a related time period may be generated and displayed on the display unit 40. Examples of a related time period are the previous month or the same month of the previous year. Displaying the forecast value informs the consumer of the probable future value of the utility consumption information or the enhanced utility consumption information. The consumer is, thereby, encouraged to take action to conserve the utility if the forecast value is high. The display of a comparison utilizing the forecast value and utility consumption information for a related time period gives the consumer a reference point by which to measure the magnitude of the data relating to the current utility consumption. Using the display of the comparison as a reference point, the consumer can determine whether the forecast value is relatively high or low for the particular time period, thereby allowing the consumer to take appropriate action to conserve the utility.

The processor 30 may also run software that utilizes the utility consumption information and the enhanced utility consumption information to provide Demand-Side management for a location. At least one utility consumption variable is selected from the utility consumption information and the enhanced utility consumption information. The utility consumption variable is the value that will be measured to determine whether action should be taken to conserve the utility. For example, the utility consumption variable could be the consumption of the utility over a time period or a comparison of the cost of consumption of the utility over a first and second time period. It is understood that more than one utility consumption variable may be selected. The input device 44 is used to select the utility consumption variable. A trigger value is set for each of the utility consumption variables selected. The input device 44 is used to set the trigger value. The trigger value is the value that, when reached, triggers or commences management of the location's utility consumption to conserve the utility. For example, a trigger value for cost of consumption of a electricity for a month may be $250. Once the utility consumption variable of cost of consumption of a utility is determined to be above the trigger value of $250, the processor 30 will manage the location's appliances to maximize utility conservation and cost savings. For example, the processor 30 may shut down the boiler or the air conditioner for a period of time via a communication medium in order to conserve the utility. It is understood that when multiple utility consumption variables are selected, the processor 30 may be set to commence Demand-Side Management upon one of the utility consumption variables reaching their corresponding trigger values or when all the utility consumption variables reach their corresponding trigger values. For example, Demand-Side Management could be set to begin when the consumption of a utility over a week is higher than it was over the previous week and the price of the utility is above fifty cents per unit. Furthermore, the processor 30 may be programmed to commence Demand-Side management when certain combinations of utility consumption variables reach their corresponding trigger values. It is also understood that the processor 30 may also provide Demand-Side Management based on the forecast of utility consumption information.

The Demand-Side Management provided by the processor 30 is more effective and efficient than current Demand-Side Management services because it is customized for a specific location based on data from that location. In addition, the processor 30 provides demand side management based on a wider variety of variables than current Demand-Side Management services. It is understood that Demand-Side Management may be carried out by the same processor 30 used to generate the enhanced utility consumption information and the displays, or it may be a separate processor coupled to the other processor 30 such that the Demand-Side Management processor receives the utility consumption information and the enhanced utility consumption information from the processor 30 used to generate the enhanced utility consumption information.

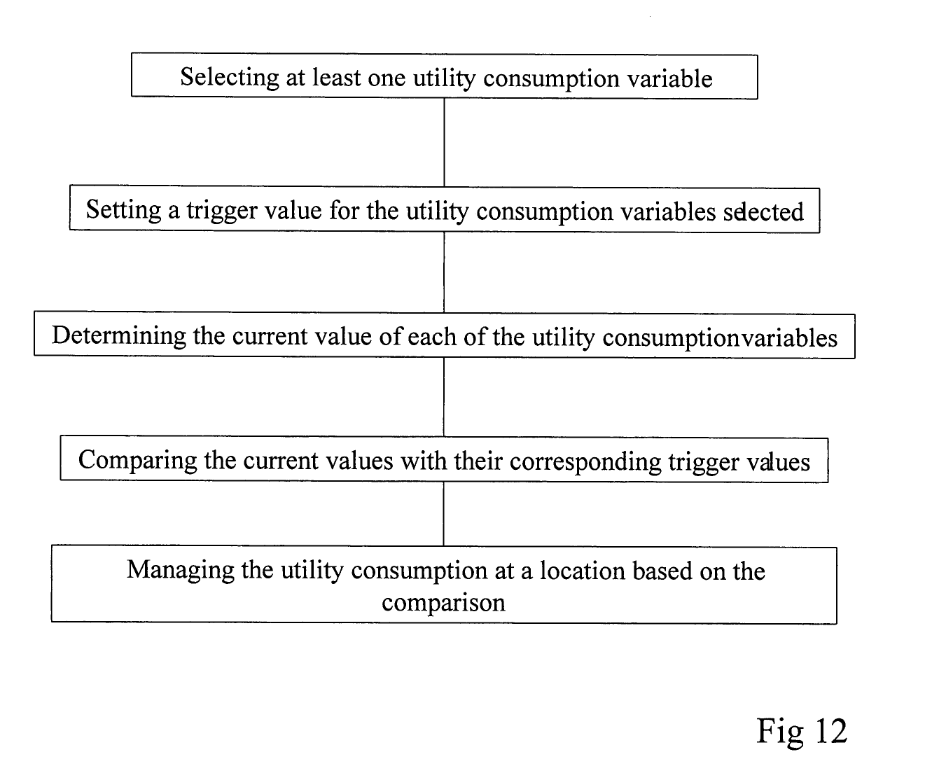

Although the present invention is shown in FIGS. 1 to 12 with the utility monitoring system and method for relaying to a customer personalized utility consumption information described above, it is understood and within the scope of the present invention that the features of the present invention may be used with any utility, in either a private or business setting. Thus, the present invention is not limited to the features and embodiments described above.

I claim:

1. A method of displaying a comparison of the consumption of a utility for at least a portion of a first time period, said first time period comprising at least one time interval, with the consumption of said utility for at least a portion of a second time period, said second time period comprising at least one time interval, comprising the steps of:
obtaining, for each of said time intervals of said portion of said first time period, a first consumption value indicative of said consumption of a utility at said time intervals;
obtaining, for each of said time intervals of said portion of said second time period, a second consumption value indicative of said consumption of a utility at said time intervals; and
generating a display showing a comparison of at least one of said first and second consumption values.

2. A method of displaying a price value related to the price of a utility for at least a portion of a time period, said time period comprising at least one time interval, comprising the steps of:
obtaining, for each of said time intervals of said portion of said time period, a price value relating to the price of said utility for said time interval; and
generating a display of a value related to said price values.

3. A method of displaying a comparison of a first price value related to the price of a utility for at least a portion of a first time period, said first time period comprising at least one time interval, with a second price value related to the price of said utility for at least a portion of a second time period, said second time period comprising at least one time interval, comprising the steps of:
obtaining, for each of said time intervals of said at least a portion of said first time period, a first price value related to the price of said utility for said time interval;
obtaining, for each of said time intervals of said at least a portion of said second period, a second price value relating to the price of said utility for said time interval; and
generating a display showing a comparison of a first value related to said first price values and a second value related to said second price values.

4. A method of displaying the cost of the consumption of a utility for at least a portion of a time period, said time period comprising at least one time interval, comprising the steps of:
obtaining, for each of said time intervals of said at least a portion of said time period, consumption value indicative of said consumption of a utility at said time interval;
obtaining, for each of said time intervals of said at least a portion of said time period, a price value relating to the price of said utility during said time interval;
generating a cost value of said consumption of said utility utilizing said consumption values and said price values;
generating a display showing said cost value.

5. A method of displaying a comparison of the cost of consumption of a utility for at least a portion of a first time period, said first time period comprising at least one time interval, with the cost of consumption of said utility for at least a portion of a second time period, said second time period comprising at least one time interval, comprising the steps of:
obtaining, for each of said time intervals of said at least a portion of said first time period, a first consumption value indicative of said consumption of a utility for said time interval;
obtaining, for each of said time intervals of said at least a portion of said first time period, a first price value relating to the price of said utility during said time interval;
generating a first cost value of said consumption of said utility utilizing said first consumption values and said first price values;
storing said first cost value;
obtaining, for each of said time intervals of said at least a portion of said second time period, a second consumption value indicative of said consumption of a utility for said time interval;
obtaining, for each of said time intervals of said at least a portion of said second time period, a second price value relating to the price of said utility during said time interval;
generating a second cost value of said consumption of said utility utilizing said second consumption values and said second price values;
generating a display showing a comparison of said first and second cost values.

6. method of providing demand-side management to a location comprising the steps of:
selecting at least one utility consumption variable;
setting a trigger value for each of said at least one utility consumption variable for at least a portion of a time period;
determining the current value for each of said at least one utility consumption variable for at least a portion of a time period;
comparing said current value for each of said at least one utility consumption variable with said at least one trigger value for each of said at least one utility consumption variable;
managing utility consumption at said location based on said comparison.

7. A method of displaying a forecast of a utility consumption variable for a time period, said time period comprising at least one time interval, comprising the steps of:
obtaining, for at least one of said time intervals of said time period, an actual value indicative of the current value of said utility consumption variable for said time interval;
generating a forecast value indicative of a forecast of the value of said utility consumption variable for said time period based on said actual values; and
generating a display of said forecast value.

8. An apparatus for displaying utility consumption information comprising:
a data source;
a processor coupled to said data source; and
a display unit coupled to said processor.

9. In apparatus for providing demand side management to a location comprising:
a data source;
a processor, coupled to said data source, said processor running software to evaluate data from said data source; and
at least one appliance located at said location, coupled to said processor, said at least one appliance having its utility consumption managed by said processor based on results of said evaluation carried out by said processor running said software.
